(19) United States
(12) Patent Application Publication
(10) Pub. No.: US 2025/0185230 A1
(43) Pub. Date: Jun. 5, 2025

(54) METHODS OF FORMING MEMORY STRUCTURES USING SEAMLESS GAPFILL

(71) Applicant: Applied Materials, Inc., Santa Clara, CA (US)

(72) Inventors: Fredrick Fishburn, Belmont, CA (US); Zhijun Chen, San Jose, CA (US); Balasubramanian Pranatharthiharan, San Jose, CA (US); Raghuveer Satya Makala, Campbell, CA (US); Lequn Liu, San Jose, CA (US)

(73) Assignee: Applied Materials, Inc., Santa Clara, CA (US)

(21) Appl. No.: 18/950,641

(22) Filed: Nov. 18, 2024

Related U.S. Application Data
(60) Provisional application No. 63/605,345, filed on Dec. 1, 2023.

(51) Int. Cl. H10B 12/00

(52) U.S. Cl. CPC H10B 12/05; H10B 12/03; H10B 12/482; H10B 12/488

(57) ABSTRACT

Methods of forming memory devices are described. The method comprises forming an oxide layer on a plurality of first layers to fill a plurality of openings in a process cycle including a first sub-cycle and a second sub-cycle. The first sub-cycle includes exposing the film stack to a silicon precursor and ammonia to form a nitride layer on each of the plurality of first layers. The second sub-cycle includes exposing the nitride layer to a plasma to form the oxide layer.

### CROSS REFERENCE TO RELATED APPLICATIONS

This application claims priority to U.S. Provisional Application Ser. No. 63/610,482, filed Dec. 15, 2023, and to U.S. Provisional Application Ser. No. 63/605,345, filed Dec. 1, 2023, the entire disclosures of which are hereby incorporated by reference herein.

### TECHNICAL FIELD

Embodiments of the present disclosure pertain to the field of electronic devices and electronic device manufacturing. More particularly, embodiments of the disclosure provide a seamless dielectric gapfill for dynamic random-access memory structures.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive word lines through the cell, the size of the cell capacitor, and the compatibility of array devices with nonarray devices. The formation of a low resistance contact between the active area and the 3D-DRAM bottom electrode is essential for performance of the device.

Gapfill processes are integral to several semiconductor manufacturing processes. A gapfill process can be used to fill a gap (or feature) with an insulating or conducting material. For example, shallow trench isolation, inter-metal dielectric layers, passivation layers, dummy gate, are all typically implemented by gapfill processes. As device geometries continue to shrink (e.g., critical dimensions <20 nm, <10 nm, and beyond), decreased metal volumes create higher resistivity for metal interconnects.

3D-DRAM integrated processes require a high aspect ratio dielectric fill process, which results in a film that has seamless fill and good wet etch rate resistance to preserve the film in subsequent processing. Dielectric breakdown and charge trapping is less of a concern for DRAM as compared to NAND due to much lower operating voltages. The gapfill in 3D-DRAM structures requires an extremely conformal deposition and there is no tolerance for retrograde profiles in either the vertical memory hole/slit or the lateral recessed layer. Current methods use atomic layer deposition to deposit silicon oxide in the lateral opening of a 3D-DRAM structure. This process results in pure silicon oxide (SiOx), but the film has a low density and a seam. Therefore, there is a need in the art for methods of filling the lateral recessed gap of 3D-DRAM structures.

### SUMMARY

One or more embodiments of the disclosure are directed to methods of forming a semiconductor device. In one or more embodiments, a method of forming a semiconductor device comprises: forming an oxide layer on each of a plurality of first layers to fill each of a plurality of openings of a film stack, the film stack comprising the plurality of first layers and the corresponding plurality of openings alternatingly arranged in a plurality of stacked pairs, in a process cycle comprising: a first sub-cycle comprising exposing the film stack to a silicon precursor and ammonia to form a nitride layer on each of the plurality of first layers, repeating the first sub-cycle t number of times, wherein t is an integer in a range of from 1 to 50; a second sub-cycle comprising exposing the nitride layer to a plasma to form the oxide layer, repeating the second sub-cycle m number of times, wherein m is an integer in a range of from 1 to 60.

Additional embodiments of the disclosure are directed to methods of forming a semiconductor device. In one or more embodiments, a method of forming a semiconductor device comprises: forming an oxide layer on each of a plurality of first layers to fill each of a plurality of lateral openings of a memory stack without a seam, the memory stack comprising the plurality of first layers including a channel and a replacement gate material and the corresponding plurality lateral openings alternatingly arranged in a plurality of stacked pairs and having a memory hole extending vertically from a top surface of the memory stack through to a bottom surface of the memory stack, in a process cycle comprising: a first-sub cycle comprising depositing a silicon oxide (SiOₓ) layer on each of the plurality of first layers and densifying the silicon oxide (SiOₓ) layer by one or more of thermal treatment or plasma treatment.

Further embodiments of the disclosure are directed to processing tools for forming a semiconductor device. In one or more embodiments, a processing tool comprises: a central transfer station having a plurality of processing chambers disposed around the central transfer station; a robot within the central transfer station configured to move a substrate between the plurality of processing chambers; a first processing chamber connected to the central transfer station, the first processing chamber configured to perform an atomic layer deposition process to deposit one or more of an oxide layer or a nitride layer on each of a plurality of first layers including a channel and a replacement gate material; a second processing chamber within the processing tool accessible to the robot, the second processing chamber comprising a rapid plasma oxidation (RPO) chamber configured to oxidize the nitride layer to form an oxide layer; a third processing chamber connected to the central transfer station, the third processing chamber comprising a thermal annealing chamber configured to densify the oxide layer; and a controller connected to the central transfer station, the robot, the first processing chamber, the rapid plasma oxidation (RPO) chamber, or the thermal annealing chamber, the controller having configurations comprising a first configuration to move a substrate on the robot between the plurality of processing chambers; a second configuration to perform the atomic layer deposition of the nitride layer; a third configuration to perform the rapid plasma oxidation (RPO) in the second processing chamber; and a fourth configuration to perform the densification of the oxide layer in the third processing chamber.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a process flow diagram of a method according to one or more embodiments;

FIG. 1B illustrates a process flow diagram of a method according to one or more embodiments;

FIG. 2A illustrates a cross-sectional view of a memory device according to one or more embodiments of the disclosure;

FIG. 2B illustrates a cross-sectional view of a memory device according to one or more embodiments of the disclosure;

FIG. 2C illustrates a cross-sectional view of a memory device according to one or more embodiments of the disclosure;

FIG. 2D illustrates a cross-sectional view of a memory device according to one or more embodiments of the disclosure;

FIG. 2E illustrates a cross-sectional view of a memory device according to one or more embodiments of the disclosure;

FIG. 2F illustrates a cross-sectional view of a memory device according to one or more embodiments of the disclosure;

FIG. 3A illustrates a cross-sectional view of a memory device according to one or more embodiments of the disclosure;

FIG. 3B illustrates a cross-sectional view of a memory device according to one or more embodiments of the disclosure;

FIG. 3C illustrates a cross-sectional view of a memory device according to one or more embodiments of the disclosure;

FIG. 3D illustrates a cross-sectional view of a memory device according to one or more embodiments of the disclosure;

FIG. 3E illustrates a cross-sectional view of a memory device according to one or more embodiments of the disclosure; and

FIG. 4 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element's relationship to other element(s) or as illustrated in the Figures. It will be understood that the spatially relative terms are intended to encompass different orientations of a device, such as a semiconductor device, in use or operation in addition to the orientation depicted in the Figures. For example, if the device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

As used in this specification and the appended claims, the term “substrate” or “wafer” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay.

Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., hydrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL), a word line is buried below the surface of a semiconductor substrate using a metal as a gate electrode.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Those skilled in the art will recognize the increasing challenge of depositing gapfill in features of narrowing width (also known as critical dimension (CD)) and/or increasing depth. The aspect ratio of the at least one feature, e.g., memory hole and lateral opening, described in the disclosure is defined as the depth D of the feature divided by the width W. In one or more embodiments, the at least one feature, e.g., memory hole and/or lateral opening, has an aspect ratio (D:W) greater than or equal to about 2:1, greater than or equal to about 5:1, greater than or equal to about 10:1, or greater than or equal to about 20:1.

In one or more embodiments, integrated processes for forming 3D-DRAM structures require a high aspect ratio dielectric fill process, resulting in a film that has seamless fill and good wet etch rate resistance to preserve the film in subsequent processing. Current dielectric fill is done by CVD or ALD, requiring an extremely conformal deposition and has no tolerance for retrograde profile in both the vertical memory hole/slit or the lateral recessed layer. Thus, one or more embodiments advantageously provides methods to deposit a dielectric layer in the lateral opening without the presence of a seam. In one or more embodiments, a first a thin silicon nitride (SiN) or silicon carbonitride (SiCN) layer is deposited by chemical vapor deposition (CVD) or atomic layer deposition (ALD) and then the film is treated, mainly by oxidation, to expand and convert the film to silicon oxide (SiOx) or silicon oxynitride (SiON). During this conversion, the nitrogen (N) level is reduced, and the oxygen (O) level is increased. The resulting layer becomes thicker, which aids in filling gaps and retrograde profiles.

Embodiments of the disclosure advantageously provide dielectric films (e.g., the oxide gapfill 234) that are free or substantially free of voids and seams. As used in this regard, “substantially free” means that less than about 5%, including less than about 4%, less than about 3%, less than about 2%, less than about 1%, less than about 0.5%, and less than about 0.1% of the total composition of the conformally deposited metal film (e.g., the oxide gapfill 234), on an atomic basis, comprises voids and/or seams.

One or more embodiments advantageously provide super-cycles of atomic layer deposition (ALD) of silicon nitride (SiN) films or silicon carbonitride (SiCN) films, followed by oxidation. In one or more embodiments, the super-cycle includes a first sub-cycle and a second sub-cycle. The first sub-cycle involves exposing a memory stack or a film stack to a silicon precursor and ammonia to form a nitride layer on each of a plurality of first layers. In some embodiments, the plurality of first layers each include a channel material and a replacement gate material. The first sub-cycle can be repeated t number of times, where t is an integer in a range of from 1 to 50. The second sub-cycle involves exposing the nitride layer to a plasma to oxidize the nitride layer and form an oxide layer. The second sub-cycle can be repeated m number of times, where m is an integer in a range of from 1 to 60. The super-cycle can be repeated n number of times, where n is an integer in a range of from 1 to 200 to fill the lateral opening with silicon oxide, silicon oxycarbonitride, silicon oxycarbide, or silicon oxynitride.

Additional embodiments provide a super-cycle of a first sub-cycle and, optionally a second sub-cycle and a third sub-cycle. In one or more alternative embodiments, the first sub-cycle involves depositing a silicon oxide (SiOₓ) layer on each of the plurality of first layers, which include a channel material and a replacement gate material and densifying the silicon oxide (SiOₓ) layer by one or more of thermal treatment or plasma treatment. The optional second sub-cycle involves exposing the densified oxide layer to a silicon precursor and ammonia to form a nitride layer on the densified oxide layer. The second sub-cycle can be repeated t number of times, where t is an integer in a range of from 1 to 50. The optional third sub-cycle involves exposing the nitride layer to a plasma to oxidize the nitride layer and form an oxide layer. The third sub-cycle can be repeated m number of times, where m is an integer in a range of from 1 to 60. The super-cycle can be repeated n number of times, where n is an integer in a range of from 1 to 200 to fill the lateral opening with silicon oxide or silicon oxynitride.

One or more embodiments of the disclosure are described with reference to the Figures. In one or more embodiments, a 3-DRAM structure having a seamless lateral dielectric gapfill is provided. In other embodiments, provided is a film stack with a seamless or substantially seamless dielectric gapfill.

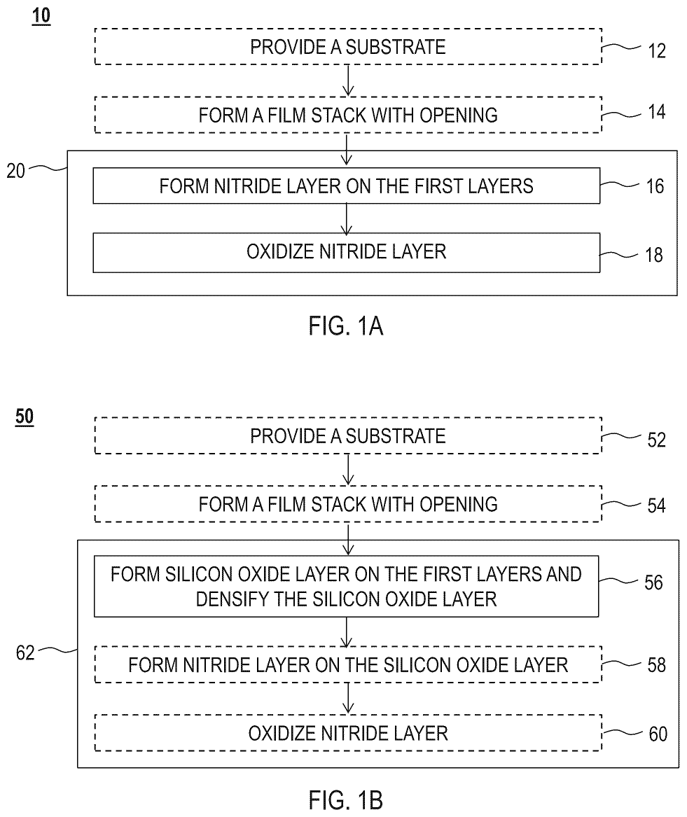

FIGS. 1A and 1B illustrate process flow diagrams for methods of forming memory structures according to one or more embodiments. The methods of one or more embodiments can include any or all of the processes illustrated. Additionally, the order of the individual processes can be varied for some portions. With reference to FIG. 1A, the method 10 can start at any of the enumerated processes without deviating from the disclosure. At operation 12, a substrate is provided. As used in this specification and the appended claims, the term “provided” means that the substrate is made available for processing (e.g., positioned in a processing chamber). At operation 14, a memory stack having a memory hole or opening patterned therein is formed. Operation 20 represents a process cycle, or super-cycle, which includes two sub-cycles, a first sub-cycle at operation 16, where a nitride layer is formed on the first layers, and a second sub-cycle at operation 18, where the nitride layer is oxidized.

With reference to FIG. 1B, the method 50 can start at any of the enumerated processes without deviating from the disclosure. At operation 52, a substrate is provided. At operation 54, a memory stack having a memory hole or opening therein is formed. Operation 62 represents a process cycle, or super-cycle, which includes one sub-cycle and two optional sub-cycles, a first sub-cycle at operation 56, where a silicon oxide layer is formed on the first layers and is densified, a second sub-cycle at operation 58, where a nitride layer is formed on the densified silicon oxide layer, and a third sub-cycle at operation 60 where the nitride layer is oxidized.

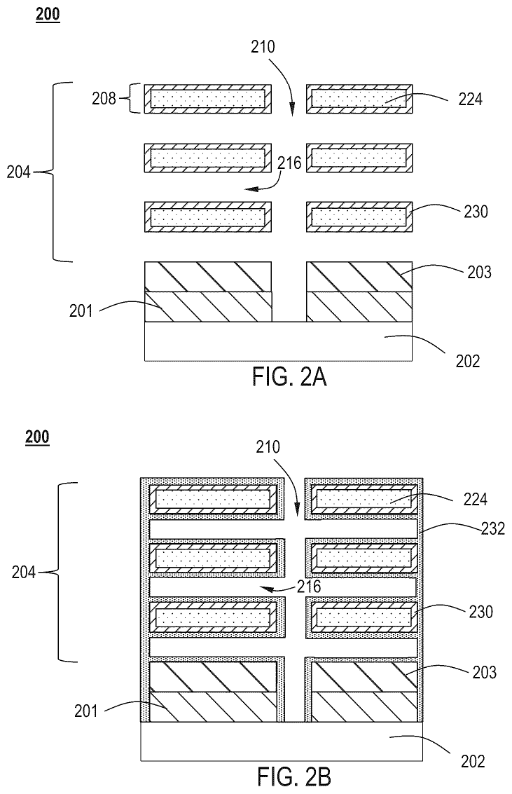

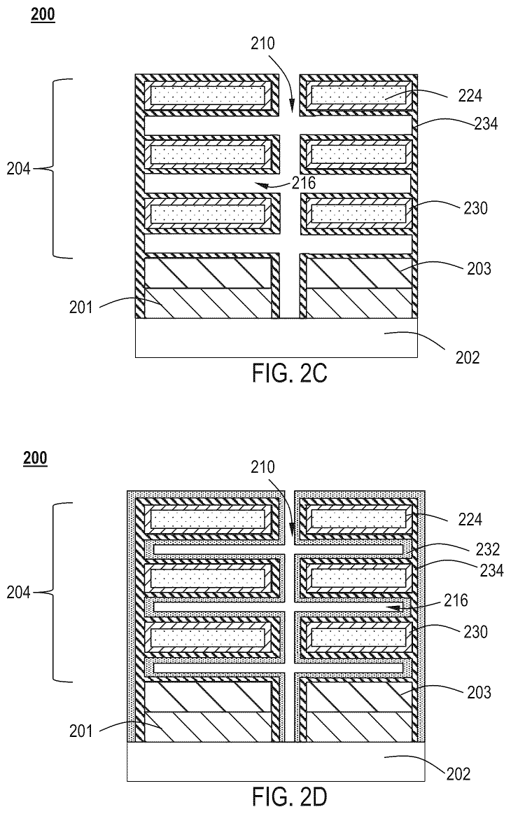

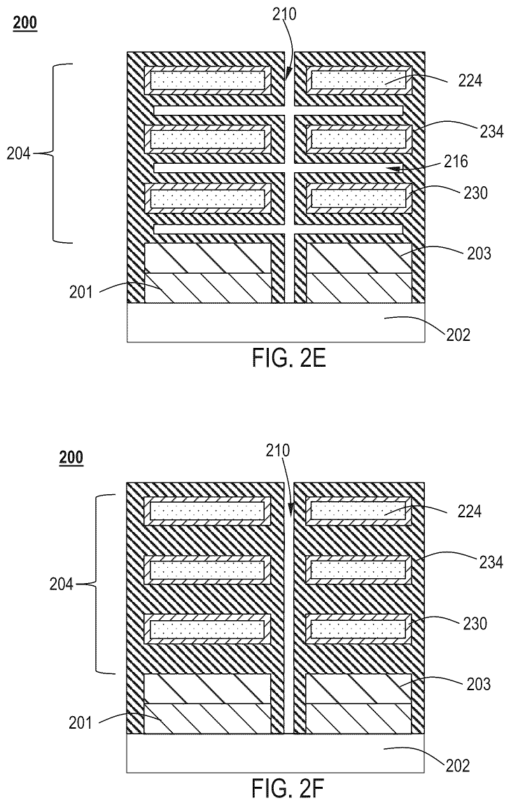

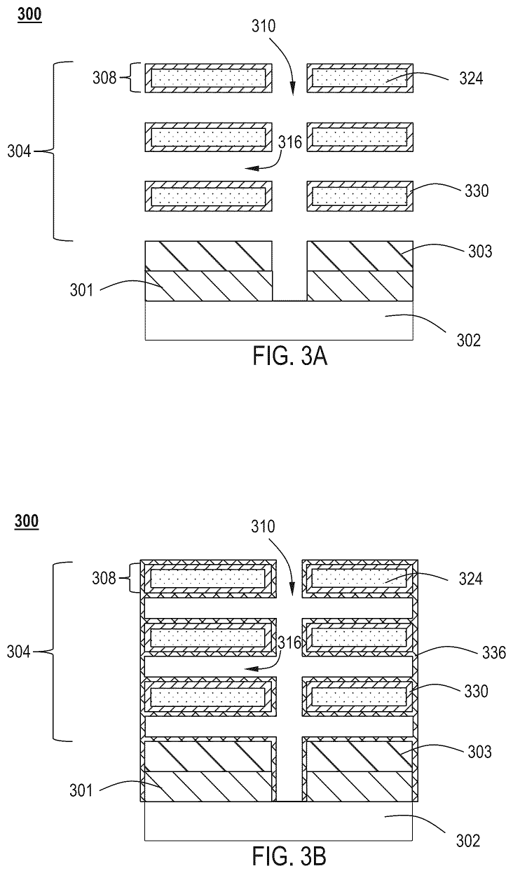

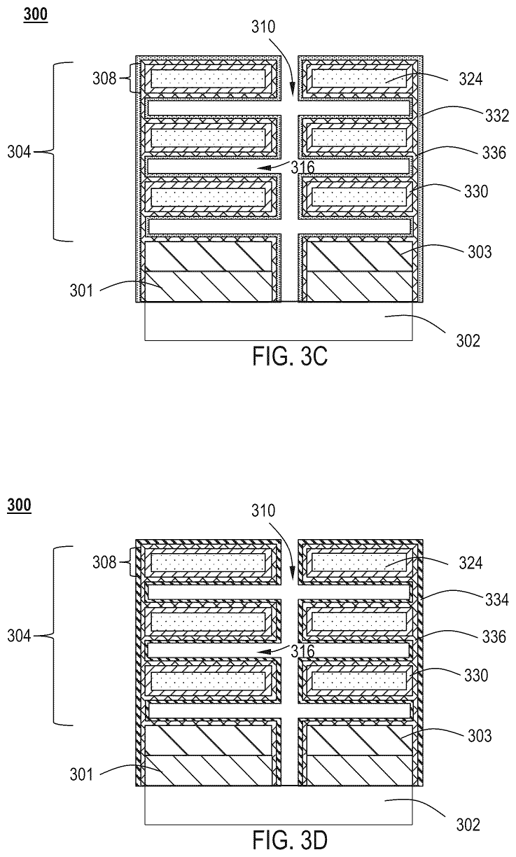

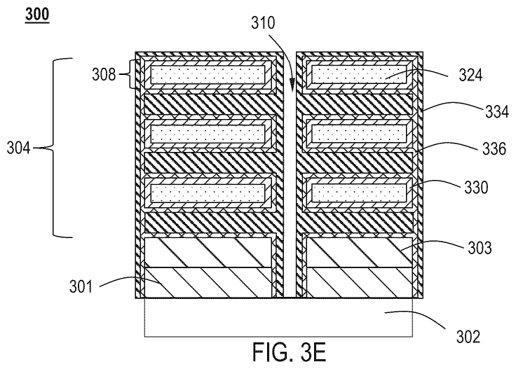

FIGS. 2A through 2F illustrate cross-sectional views of a memory device according to one or more embodiments and the method of FIG. 1A. FIGS. 3A through 3E illustrate cross-section views of a memory device manufactured according to one or more embodiments and the method of FIG. 1B.

With reference to FIG. 2A, an initial or starting mold of an electronic device 200 is provided or form in accordance with one or more embodiments of the disclosure. In some embodiments, the electronic device 200 shown in FIG. 2A is formed on a bare substrate (not illustrated) in layers. In one or more embodiments, the electronic device of FIG. 2A is made up of a substrate 202, one or more optional semiconductor layers 201,203, and a memory stack or film stack 204.

The substrate 202 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

In one or more embodiments, an optional first semiconductor layer 201 is on the substrate 202, and an optional second semiconductor layer 203 is on the optional first semiconductor layer 201. The semiconductor layers 201, 203 may comprise any suitable material known to the skilled artisan. In one or more embodiments, semiconductor layers 201, 203 comprise an insulating layer.

In other embodiments, the optional semiconductor layers 201, 203 may also be referred to as the semiconductor material layers or active layers. As used herein, the term “active” or “memory layer” refers to a layer of material in which a channel, a bit line, a word line, or a capacitor can be made. In one or more embodiments, the active layer comprises one or more of silicon or doped silicon.

In some embodiments, the semiconductor layers 201, 203 may be a doped material, such as n-doped silicon (n-Si), or p-doped silicon (p-Si). In some embodiments, the semiconductor layers 201, 203 may be doped using any suitable process such as an ion implantation process. As used herein, the term “n-type” refers to semiconductor material layer that is created by doping with an electron donor element during manufacture. The term n-type comes from the negative charge of the electron. In n-type semiconductor material layers, electrons are the majority carriers and holes are the minority carriers. As used herein, the term “p-type” refers to the positive charge of a well (or hole). As opposed to n-type semiconductor materials, p-type semiconductor materials have a larger hole concentration than electron concentration. In p-type semiconductor materials, holes are the majority carriers and electrons are the minority carriers. In one or more embodiments, the dopant is selected from one or more of boron (B), gallium (Ga), phosphorus (P), arsenic (As), other semiconductor dopants, or combinations thereof. In some embodiments, the second sacrificial layer 203 comprises several different conductive or semiconductor materials.

In some embodiments, one or more of the semiconductor layers 201, 203 may be removed and replaced in later processes. In some embodiments, one or more of the semiconductor layers 201, 203 are not removed and remain within the device 200. In this case, the term “sacrificial” has an expanded meaning to include permanent layers and may be referred to as the conductive layer. In one or more embodiments, one or more of the semiconductor layers 201, 203 can be removed selectively versus the layers of the neighboring memory stack or film stack 204.

The memory stack or film stack 204 in the illustrated embodiment comprises a plurality of alternating first layers 208 including a channel 224 and replacement gate material 230, and a plurality of lateral openings 216 extending horizontally between the plurality of first layers 208. One of skill in the art recognizes that the plurality of first layers 208 may not include a channel 224 and a replacement gate material 230 depending upon when in the device fabrication process the film stack is being processed. While the memory stack or film stack 204, illustrated in FIG. 2A, has a three sets of alternating first layers 208 and lateral openings 216, one of skill in the art recognizes that this is merely for illustrative purposes only. In some embodiments, the openings 216 may not be lateral, but, rather, may be vertically aligned depending upon the orientation of the film stack 204. The memory stack or film stack 204 may have any number of alternating first layers 208 and lateral openings 216. For example, in some embodiments, the memory stack or film stack 204 comprises 192 pairs of alternating first layers 208 and lateral openings 216. In other embodiments, the memory stack or film stack 204 comprises greater than 50 pairs of alternating first layers 208 and lateral openings 216, or greater than 200 pairs of alternating first layers 208 and lateral openings 216, or greater than 300 pairs of alternating first layers 208 and lateral openings 216.

In one or more embodiments, sequential depositions are used to form many active area regions. In one or more embodiments, alternating layers of films, e.g., oxide-polysilicon, polysilicon-nitride, oxide-nitride, silicon-silicon germanium, are deposited.

In one or more embodiments, the first layers 208 may include a channel 224 and a replacement gate material 230. In some embodiments, the replacement gate material 230 comprises silicon germanium (SiGe) having in a range of from 10% to 25% germanium. In one or more embodiments, the channel 224 comprises silicon (Si).

The individual alternating layers and lateral openings may be formed to any suitable thickness. In some embodiments, the thickness of each first layer 208 is approximately equal. As used in this regard, thicknesses which are approximately equal are within +/−5% of each other. In one or more embodiments, the first layers 208 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments the first layer 208 has a thickness in the range of from about 0.5 to about 40 nm.

Referring to FIG. 2A, the device has a patterned memory hole or opening 210.

The memory hole or opening 210 extends a distance into the substrate 202 so that the sidewall surface and the bottom of the memory hole or opening 210 are formed within the substrate 202. The bottom of the memory hole or opening 210 can be formed at any point within the thickness of the substrate 202. In some embodiments, the memory hole or opening 210 extends a thickness into the substrate 202 in the range of from about 10% to about 90%, or in the range of from about 20% to about 80%, or in the range of from about 30% to about 70%, or in the range of from about 40% to about 60% of the thickness of the substrate 201. In some embodiments, the memory hole or opening 210 extends a distance into the substrate 202 by greater than or equal to 10%, 20%, 30%, 40%, 50%, 60%, 70% or 80% of the thickness of the substrate 202.

In one or more embodiments, the lateral recessed region 216 extending between adjacent first layers 208 may have any suitable width known to the skilled artisan. In one or more embodiments, the lateral opening or recessed region 216 has a width in a range of from 5 nm to 40 nm, including a width in a range of from 5 nm to 30 nm, or in a range of from 10 nm to 40 nm, or in a range of from 10 nm to 30 nm, or in a range of from 15 nm to 25 nm.

With reference to FIG. 2B, a nitride layer 232 is deposited through the memory hole or opening 210 and into the recessed region 216 onto and around the first layer 208. The nitride layer 232 may comprise any suitable material known to the skilled artisan. The nitride layer 232 can be deposited using one or more deposition techniques known to the skilled artisan. In one or more embodiments, the nitride layer 232 is formed according to the method 10 of FIG. 1A.

In one or more embodiments, the nitride layer 232 is formed by ALD or CVD. The nitride layer 232 may comprise any suitable material known to the skilled artisan. In one or more embodiments, the nitride layer 232 comprises silicon nitride (SiN) or silicon carbonitride (SiCN). In one or more embodiments, the nitride layer 232 comprises silicon nitride (SiₓN_{y}). The nitride layer may have any suitable thickness known to the skill artisan. In one or more embodiments, the nitride layer has a thickness in a range of from 1 nm to 25 nm, including in a range of from 1 nm to 15 nm, or in a range of from 5 nm to 20 nm, or in a range of from 1 nm to 5 nm.

In one or more embodiments, to deposit the nitride layer 232, a first sub-cycle includes exposing the memory stack or film stack 204 to a silicon precursor and ammonia to form the nitride layer 232 on each of the plurality of first layers 208. The silicon precursor may include any suitable silicon precursor known to the skilled artisan. In one or more embodiments, the silicon precursor comprises a silane (SiH₄) or a poly-silane (SiₓH_{y}). In some embodiments, the poly-silane is selected from disilane (Si₂H₆), trisilane (Si₃H₈),, tetrasilane (Si₄H₁₀), isotetrasilane, neopentasilane (Si₅H₁₂), cyclopentasilane (Si₅H₁₀), hexasilane (Si₆H₁₄), cyclohexasilane (Si₆H₁₂).

In one or more embodiments, the first sub-cycle to form the thin nitride layer 232 may be repeated t number of times, where t is an integer in a range of from 1 to 50.

Referring to FIG. 2C, in a second sub-cycle, the nitride layer 232 may be exposed to a plasma to oxidize the nitride layer and form an oxide layer 234. The oxide layer 234 may have any suitable thickness known to the skill artisan. In one or more embodiments, the oxide layer 234 has a thickness in a range of from 1 nm to 25 nm, including in a range of from 1 nm to 15 nm, or in a range of from 5 nm to 20 nm, or in a range of from 1 nm to 5 nm. Without intending to be bound by theory, during the conversion of the nitride layer 232 to the oxide layer 234, the nitrogen (N) level is reduced and the oxygen (O) level in increased. The resulting oxide layer becomes thicker, which aids in filling gaps and retrograde profiles. Thus, in one or more embodiments, oxidizing the nitride layer 232 to form the oxide layer 234 increases or expands the thickness of the layer, such that the oxide layer 234 has a thickness that is greater than the thickness of the nitride layer 232.

In one or more embodiments, the second sub-cycle is one or more of a rapid plasma oxidation (RPO) process, a thermal oxidation process, and a rapid thermal anneal (RTA) process. In some embodiments, the RPO process exposes the nitride layer 232 to an oxygen-containing plasma (e.g., molecular oxygen (O₂), ozone (O₃)) at a temperature in the range of 350° C. to 650° C., pressure ranging from 5-300 Torr to form the oxide layer 234.

In one or more alternative embodiments, the nitride layer 232 deposited is graded for oxygen (O) and nitrogen (N) content to form a nitride layer 232 and an oxide layer 234 having an oxygen/nitrogen gradient. As used herein, the term “gradient” refers to a variation in the concentration throughout the thickness of a material. In other words, the nitride layer 232 and oxide layer 234 form an oxygen/nitrogen gradient in which the concentration of nitrogen (N) and oxygen (O) gradually changes. In one or more embodiments, the nitrogen (N) concentration ranges from low to high, until the lateral opening 216 is filled completely, where the nitrogen (N) concentration is lowest at the interface with the first layers 208 and highest in the middle of the lateral opening 216. In one or more embodiments, the concentration of nitrogen (N) in the filled lateral opening 216 is in a range of from greater than 0% to 50%, including in a range of from 1% to 25%, or in a range of from 3% to 20%. In one or more embodiments, the oxidation volume expansion helps to fill the potential voids in the lateral opening 216.

In one or more embodiments, the oxide layer 234 comprises any suitable material known to the skilled artisan. In some embodiments, the oxide layer 234 comprises one or more of silicon oxide (SiOₓ), silicon oxycarbonitride (SiOCN), silicon oxycarbide (SiOC), or silicon oxynitride (SiON). In one or more embodiments, the second sub-cycle to form the thin oxide layer 234 may be repeated m number of times, where t is an integer in a range of from 1 to 60. The process cycle 20 illustrated in FIG. 1A and FIGS. 2A to 2E can be repeated n number of times, where n is an integer in a range of from 1 to 100 to fill the lateral opening or recessed region 216 with an oxide layer 234 without the presence of a seam, as illustrated in FIG. 2F.

Referring to FIGS. 1B and FIGS. 3A-3E, with reference to FIG. 3A, an initial or starting mold of an electronic device 300 is provided or formed in accordance with one or more embodiments of the disclosure. In some embodiments, the electronic device 300 shown in FIG. 3A is formed on a bare substrate (not illustrated) in layers. In one or more embodiments, the electronic device of FIG. 3A is made up of a substrate 302, one or more optional semiconductor layers 301,303, and a memory stack 304 or film stack 304.

The substrate 302 can be any suitable material known to the skilled artisan and as described above with respect to FIGS. 2A through 2F.

In one or more embodiments, an optional first semiconductor layer 301 is on the substrate 302, and an optional second semiconductor layer 303 is on the optional first semiconductor layer 301. The semiconductor layers 301, 303 may comprise any suitable material known to the skilled artisan. In one or more embodiments, semiconductor layers 301, 303 comprise an insulating layer.

The optional semiconductor layers 301,303 may also be referred to as the semiconductor material layers or the active layers. The optional semiconductor layers 301,303 can be formed by any suitable technique known to the skilled artisan and can be made from any suitable material as described above with respect to FIGS. 2A through 2F.

In some embodiments, one or more of the semiconductor layers 301, 303 may be removed and replaced in later processes. In some embodiments, one or more of the semiconductor layers 301, 303 are not removed and remain within the memory device 300. In this case, the term “sacrificial” has an expanded meaning to include permanent layers and may be referred to as the conductive layer. In one or more embodiments, one or more of the semiconductor layers 301, 303 can be removed selectively versus the layers of the neighboring memory stack 304.

The memory stack or film stack 304 in the illustrated embodiment comprises a plurality of alternating first layers 308 including a channel 324 and replacement gate material 330, and a plurality of lateral openings 316 extending horizontally between the plurality of first layers 308. One of skill in the art recognizes that the plurality of first layers 308 may not include a channel 324 and a replacement gate material 330 depending upon when in the device fabrication process the film stack is being processed. While the memory stack or film stack 304, illustrated in FIG. 3A, has a three sets of alternating first layers 308 and lateral openings 316, one of skill in the art recognizes that this is merely for illustrative purposes only. Additionally, in some embodiments, the openings 316 may not be lateral, but, rather, may be vertically aligned depending upon the orientation of the film stack 304. The memory stack or film stack 304 may have any number of alternating first layers 308 and lateral opening 316. For example, in some embodiments, the memory stack or film stack 304 comprises 192 pairs of alternating first layers 308 and lateral openings 316. In other embodiments, the memory stack or film stack 304 comprises greater than 50 pairs of alternating first layers 308 and lateral openings 316, or greater than 200 pairs of alternating first layers 308 and lateral openings 316, or greater than 300 pairs of alternating first layers 308 and lateral openings.

In one or more embodiments, the first layers 308 may include a channel 324 and a replacement gate material 330. In some embodiments, the replacement gate material 330 comprises silicon germanium (SiGe) having in a range of from 10% to 25% germanium. In one or more embodiments, the channel 324 comprises silicon (Si).

In some embodiments, the thickness of each first layer 308 is approximately equal. As used in this regard, thicknesses which are approximately equal are within +/−5% of each other. In one or more embodiments, the first layers 308 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments the first layer 308 has a thickness in the range of from about 0.5 to about 40 nm.

Referring to FIG. 3A, the device has a patterned memory hole or opening 310. The memory hole or opening 310 extends a distance into the substrate 302 so that the sidewall surface and the bottom of the memory hole or opening 310 are formed within the substrate 302. The bottom of the memory hole or opening 310 can be formed at any point within the thickness of the substrate 302. In some embodiments, the memory hole or opening 310 extends a thickness into the substrate 302 in the range of from about 10% to about 90%, or in the range of from about 20% to about 80%, or in the range of from about 30% to about 70%, or in the range of from about 40% to about 60% of the thickness of the substrate 302. In some embodiments, the memory hole or opening 310 extends a distance into the substrate 202 by greater than or equal to 10%, 20%, 30%, 40%, 50%, 60%, 70% or 80% of the thickness of the substrate 302.

In one or more embodiments, the lateral recessed region 316 may have any suitable width known to the skilled artisan. In one or more embodiments, the lateral opening or recessed region 316 has a width in a range of from 5 nm to 40 nm, including a width in a range of from 5 nm to 30 nm, or in a range of from 10 nm to 40 nm, or in a range of from 10 nm to 30 nm, or in a range of from 15 nm to 25 nm.

Referring to FIG. 1B and FIGS. 3B to 3D, in one or more embodiments, at process cycle 60 an oxide layer 334 is formed and around on each of a plurality of first layers 308 including a channel 324 and a replacement gate material 330 to fill each of the plurality of lateral openings 316 without or substantially without a seam. In one or more embodiments, the process cycle 62 includes a first sub-cycle 56, an optional second sub-cycle 58, and an optional third sub-cycle 60. In one or more embodiments, a first sub-cycle 56 includes depositing a silicon oxide (SiOₓ) layer on and around each of the plurality of first layers 308 and densifying the silicon oxide (SiOₓ) layer by one or more of thermal treatment or plasma treatment to form a densified silicon oxide (SiOₓ) layer 336. In one or more embodiments, densifying the silicon oxide (SiOₓ) layer to form the densified silicon oxide (SiOₓ) layer 336 is a rapid thermal annealing (RTA) processing in an atmosphere of oxygen (O₂), nitrogen oxide (N₂O), and the like.

In other embodiments, a silicon (Si) rich silicon oxide (SiOₓ) layer is deposited by atomic layer deposition (ALD), which is then treated with plasma to densify and form the densified silicon oxide (SiOₓ) layer 336. As used herein, the term “silicon (Si) rich” refers to a silicon oxide layer having a greater percentage of silicon than a silicon oxide (SiO₂) layer. Thus, in one or more embodiments, a silicon rich silicon oxide (SiOₓ) layer where x is in a range of from 1 to less than 2 is deposited on and around each of the plurality of first layers 308 forming a silicon rich oxide liner on and around the first layers 308 at the interface of two adjacent first layers 308. The silicon rich oxide liner may then be densified with a plasma (RPO) treatment to form the densified silicon oxide layer (SiOₓ) layer 336.

With reference to FIG. 3C, a nitride layer 332 is deposited through the memory hole opening 310 and into the lateral opening 316 onto and around the densified silicon oxide (SiO₂) layer 336. The nitride layer 332 may comprise any suitable material known to the skilled artisan. The nitride layer 332 can be deposited using one or more deposition techniques known to the skilled artisan. In one or more embodiments, the nitride layer 332 is formed according to the method 50 of FIG. 1B.

In one or more embodiments, the nitride layer 332 is formed by ALD or CVD. The nitride layer 332 may comprise any suitable material known to the skilled artisan. In one or more embodiments, the nitride layer 332 comprises silicon nitride (SiN) or silicon carbonitride (SiCN). In one or more embodiments, the nitride layer 332 comprises silicon nitride (SiₓN_{y}). The nitride layer 332 may have any suitable thickness known to the skill artisan. In one or more embodiments, the nitride layer has a thickness in a range of from 1 nm to 25 nm, including in a range of from 1 nm to 15 nm, or in a range of from 5 nm to 20 nm, or in a range of from 1 nm to 5 nm.

In one or more embodiments, to deposit the nitride layer 332, a second sub-cycle includes exposing the memory stack or film stack 304 to a silicon precursor and ammonia to form the nitride layer 332 on each of the densified silicon oxide (SiO₂) layer 336. The silicon precursor may include any suitable silicon precursor known to the skilled artisan. In one or more embodiments, the silicon precursor comprises a silane (SiH₄) or a poly-silane (SiₓH_{y}). In some embodiments, the poly-silane is selected from disilane (Si₂H₆), trisilane (Si₃H₈), tetrasilane (Si₄H₁₀), isotetrasilane, neopentasilane (Si₅H₁₂), cyclopentasilane (Si₅H₁₀), hexasilane (Si₆H₁₄), cyclohexasilane (Si₆H₁₂).

In one or more embodiments, the second sub-cycle to form the thin nitride layer 332 may be repeated t number of times, where t is an integer in a range of from 1 to 50.

Referring to FIG. 3D, in a third sub-cycle, the nitride layer 332 may be exposed to a plasma to oxidize the nitride layer and form an oxide layer 334. The oxide layer 334 may have any suitable thickness known to the skill artisan. In one or more embodiments, the oxide layer 334 has a thickness in a range of from 1 nm to 25 nm, including in a range of from 1 nm to 15 nm, or in a range of from 5 nm to 20 nm, or in a range of from 1 nm to 5 nm. Without intending to be bound by theory, during the conversion of the nitride layer 332 to the oxide layer 334, the nitrogen (N) level is reduced and the oxygen (O) level in increased. The resulting oxide layer becomes thicker, which aids in filling gaps and retrograde profiles. Thus, in one or more embodiments, oxidizing the nitride layer 332 to form the oxide layer 334 increases or expands the thickness of the layer, such that the oxide layer 334 has a thickness that is greater than the thickness of the nitride layer 332.

In one or more embodiments, the second sub-cycle is one or more of a rapid plasma oxidation (RPO) process, a thermal oxidation process, and a rapid thermal anneal (RTA) process. In some embodiments, the RPO process exposes the nitride layer 332 to an oxygen-containing plasma (e.g., molecular oxygen (O₂), ozone (O₃)) at a temperature in the range of 350° C. to 650° C., pressure ranging from 5 Torr to 300 Torr to form the oxide layer 334.

In one or more alternative embodiments, the nitride layer 332 deposited is graded for oxygen (O) nitrogen (N) content to form a nitride layer 332 and an oxide layer 334 having an oxygen/nitrogen gradient. As used herein, the term “gradient” refers to a variation in the concentration throughout the thickness of a material. In other words, the nitride layer 332 and oxide layer 334 form an oxygen/nitrogen gradient in which the concentration of nitrogen (N) and oxygen (O) gradually changes. In one or more embodiments, the nitrogen (N) concentration ranges from low to high, until the lateral opening 316 is filled completely, where the nitrogen (N) concentration is lowest at the interface with the first layers 308 and highest in the middle of the lateral opening 316. In one or more embodiments, the concentration of nitrogen (N) is in the filled lateral opening 216 is in a range of from greater than 0% to 50%, including in a range of from 1% to 25%, or in a range of from 3% to 20%. In one or more embodiments, the oxidation volume expansion helps to fill the potential voids in the lateral opening 316.

In one or more embodiments, the oxide layer 334 comprises any suitable material known to the skilled artisan. In some embodiments, the oxide layer 334 comprises one or more of silicon oxide (SiOx), silicon oxycarbide (SiOC), silicon oxycarbonitride (SiOCN), or silicon oxynitride (SiON). In one or more embodiments, the second sub-cycle to form the thin oxide layer 334 may be repeated m number of times, where t is an integer in a range of from 1 to 60. The process cycle 60 illustrated in FIG. 1B and FIGS. 3B to 3D can be repeated n number of times, where n is an integer in a range of from 1 to 100 to fill the lateral opening or recessed region 316 with an oxide layer 334 without the presence of a seam, as illustrated in FIG. 3E.

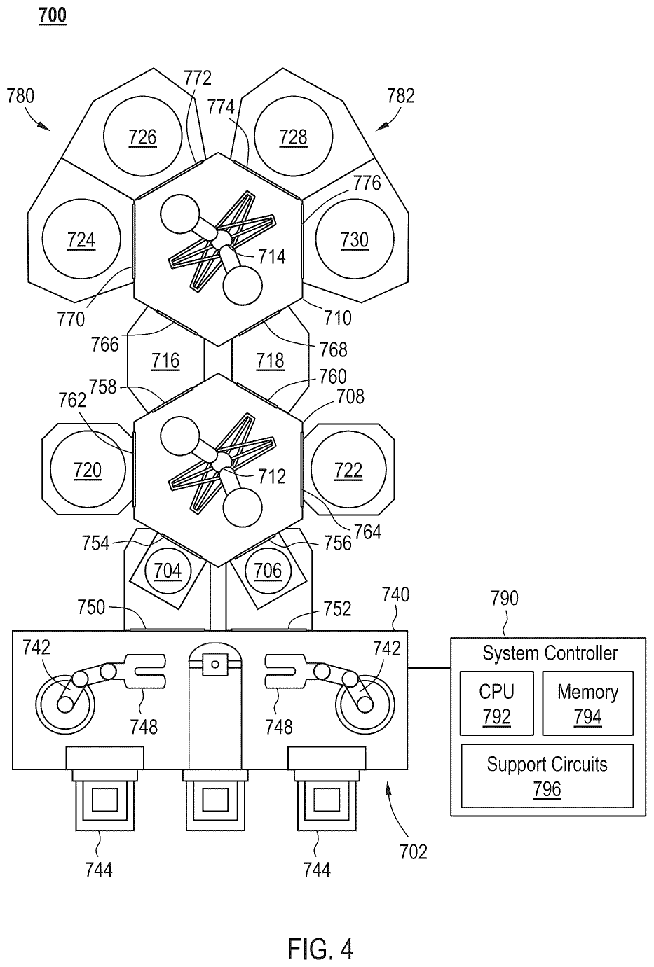

Additional embodiments of the disclosure are directed to processing tools 300 for the formation of the memory devices, e.g., 3-D DRAM devices, and methods described, as shown in FIG. 4. FIG. 4 illustrates a schematic top-view diagram of an example of a multi-chamber processing system 700 according to embodiments of the present disclosure. The processing system 700 generally includes a factory interface 702, load lock chambers 704, 706, transfer chambers 708, 710 with respective transfer robots 712, 714, holding chambers 716, 718, and processing chambers 720, 722, 724, 726, 728, 730. As detailed herein, wafers in the processing system 700 can be processed in and transferred between the various chambers without exposing the wafers to an ambient environment exterior to the processing system 700 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 700. Accordingly, the processing system 700 may provide an integrated solution for some processing of wafers.

In one or more embodiments integrated, processing systems or other suitable processing systems may be adapted to benefit from aspects described herein.

In the illustrated example of FIG. 4, the factory interface 702 includes a docking station 740 and factory interface robots 742 to facilitate transfer of wafers. The docking station 740 is configured to accept one or more front opening unified pods (FOUPs) 744. In some examples, each factory interface robot 742 generally comprises a blade 748 disposed on one end of the respective factory interface robot 742 configured to transfer the wafers from the factory interface 702 to the load lock chambers 704, 706.

The load lock chambers 704, 706 have respective ports 750, 752 coupled to the factory interface 702 and respective ports 754, 756 coupled to the transfer chamber 708. The transfer chamber 708 further has respective ports 758, 760 coupled to the holding chambers 716, 718 and respective ports 762, 764 coupled to processing chambers 720, 722. Similarly, the transfer chamber 710 has respective ports 766, 768 coupled to the holding chambers 716, 718 and respective ports 770, 772, 774, 776 coupled to processing chambers 724, 726, 728, 730. The ports 754, 756, 758, 760, 762, 764, 766, 768, 770, 772, 774, 776 can be, for example, slit valve openings with slit valves for passing wafers therethrough by the transfer robots 712, 714 and for providing a seal between respective chambers to prevent a gas from passing between the respective chambers. Generally, any port is open for transferring a wafer therethrough. Otherwise, the port is closed.

The load lock chambers 704, 706, transfer chambers 708, 710, holding chambers 716, 718, and processing chambers 720, 722, 724, 726, 728, 730 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 742 transfers a wafer from a FOUP 744 through a port 750 or 752 to a load lock chamber 704 or 706. The gas and pressure control system then pumps down the load lock chamber 704 or 706. The gas and pressure control system further maintains the transfer chambers 708, 710 and holding chambers 716, 718 with an interior low pressure or vacuum environment (which may include an inert gas). Hence, the pumping down of the load lock chamber 704 or 706 facilitates passing the wafer between, for example, the atmospheric environment of the factory interface 702 and the low pressure or vacuum environment of the transfer chamber 708.

With the wafer in the load lock chamber 704 or 706 that has been pumped down, the transfer robot 712 transfers the wafer from the load lock chamber 704 or 706 into the transfer chamber 708 through the port 754 or 756. The transfer robot 712 is then capable of transferring the wafer to and/or between any of the processing chambers 720, 722 through the respective ports 762, 764 for processing and the holding chambers 716, 718 through the respective ports 758, 760 for holding to await further transfer. Similarly, the transfer robot 714 is capable of accessing the wafer in the holding chamber 716 or 718 through the port 766 or 768 and is capable of transferring the wafer to and/or between any of the processing chambers 724, 726, 728, 730 through the respective ports 770, 772, 774, 776 for processing and the holding chambers 716, 718 through the respective ports 766, 768 for holding to await further transfer. The transfer and holding of the wafer within and among the various chambers can be in the low pressure or vacuum environment provided by the gas and pressure control system.

The processing chambers 720, 722, 724, 726, 728, 730 can be any appropriate chamber for processing a wafer. The processing chambers 720, 722, 724, 726, 728, 730 can one or more of a rapid thermal annealing chamber, a thermal oxidation chamber, rapid plasma oxidation (RPO) chamber, and the like. In some embodiments, the processing chamber 720 can be capable of performing an annealing process, the processing chamber 722 can be capable of performing a cleaning process, and the processing chambers 724, 726, 728, 730 can be capable of performing epitaxial growth processes. In some examples, the processing chamber 722 can be capable of performing a cleaning process, the processing chamber 720 can be capable of performing an etch process, and the processing chambers 724, 726, 728, 730 can be capable of performing respective epitaxial growth processes. The processing chamber 722 may be any suitable pre-clean chamber. The processing chamber 720 may be any suitable etch chamber.

A system controller 790 is coupled to the processing system 400 for controlling the processing system 700 or components thereof. For example, the system controller 790 may control the operation of the processing system 700 using a direct control of the chambers 704, 706, 708, 716, 718, 710, 720, 722, 724, 726, 728, 730 of the processing system 700 or by controlling controllers associated with the chambers 704, 706, 708, 716, 718, 710, 720, 722, 724, 726, 728, 730. In operation, the system controller 790 enables data collection and feedback from the respective chambers to coordinate performance of the processing system 700.

The system controller 790 generally includes a central processing unit (CPU) 792, memory 794, and support circuits 796. The CPU 792 may be one of any form of a general-purpose processor that can be used in an industrial setting. The memory 794, or non-transitory computer-readable medium, is accessible by the CPU 792 and may be one or more of memory such as random-access memory (RAM), read only memory (ROM), floppy disk, hard disk, or any other form of digital storage, local or remote. The support circuits 796 are coupled to the CPU 792 and may comprise cache, clock circuits, input/output subsystems, power supplies, and the like. The various methods disclosed herein may generally be implemented under the control of the CPU 792 by the CPU 792 executing computer instruction code stored in the memory 794 (or in memory of a particular process chamber) as, for example, a software routine. When the computer instruction code is executed by the CPU 792, the CPU 792 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 708, 710 and the holding chambers 716, 718. In other examples, more or fewer transfer chambers (e.g., one transfer chamber) and/or more or fewer holding chambers (e.g., no holding chambers) may be implemented as a transfer apparatus in a processing system.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
forming an oxide layer on each of a plurality of first layers to fill each of a plurality of openings of a film stack, the film stack comprising the plurality of first layers and the corresponding plurality of openings alternatingly arranged in a plurality of stacked pairs, in a process cycle comprising:
a first sub-cycle comprising exposing the film stack to a silicon precursor and ammonia to form a nitride layer on each of the plurality of first layers, repeating the first sub-cycle t number of times, wherein t is an integer in a range of from 1 to 50; and
a second sub-cycle comprising exposing the nitride layer to a plasma to form the oxide layer, repeating the second sub-cycle m number of times, wherein m is an integer in a range of from 1 to 60.

2. The method of claim 1, further comprising repeating the process cycle n number of times, wherein n is an integer in a range of from 1 to 200.

3. The method of claim 1, further comprising depositing a silicon oxide (SiOₓ) layer on each of the plurality of first layers and densifying the silicon oxide (SiOₓ) layer by one or more of thermal treatment or plasma treatment before performing the first sub-cycle.

4. The method of claim 1, wherein the nitride layer comprises silicon nitride (SiₓN_{y}) or silicon carbonitride (SiCN).

5. The method of claim 1, wherein the nitride layer has a thickness in a range of from 1 nm to 25 nm.

6. The method of claim 1, wherein the silicon precursor comprises a silane or a poly-silane (SiₓH_{y}).

7. The method of claim 1, wherein the process cycle forms an oxygen/nitrogen gradient where a concentration of nitrogen (N) is lowest at an interface with each of the plurality of first layers and highest in a middle of each of the plurality of openings.

8. The method of claim 1, wherein the oxide layer comprises one or more of silicon oxide (SiO₂), silicon oxycarbide (SiOC), silicon oxycarbonitride (SiOCN), or silicon oxynitride (SiON).

9. The method of claim 1, wherein each of the plurality of openings is filled by the oxide layer without a seam.

10. The method of claim 1, wherein the second sub-cycle comprises a rapid plasma oxidation (RPO) process, a thermal oxidation process, and a rapid thermal anneal (RTA) process.

11. A method of forming a semiconductor device, the method comprising:
forming an oxide layer on each of a plurality of first layers to fill each of a plurality of lateral openings of a memory stack without a seam, the memory stack comprising the plurality of first layers including a channel and a replacement gate material and the corresponding plurality lateral openings alternatingly arranged in a plurality of stacked pairs and having a memory hole extending vertically from a top surface of the memory stack through to a bottom surface of the memory stack, in a process cycle comprising:
a first-sub cycle comprising depositing a silicon oxide (SiOₓ) layer on each of the plurality of first layers and densifying the silicon oxide (SiOₓ) layer by one or more of thermal treatment or plasma treatment.

12. The method of claim 11, further comprising:
a second sub-cycle comprising exposing the densified oxide layer to a silicon precursor and ammonia to form a nitride layer on the densified oxide layer, repeating the second sub-cycle t number of times, wherein t is an integer in a range of from 1 to 50;
a third sub-cycle comprising exposing the nitride layer to a plasma to form the oxide layer, repeating the third sub-cycle m number of times, wherein m is an integer in a range of from 1 to 60; and
optionally, repeating the process cycle n number of times, wherein n is an integer in a range of from 1 to 200.

13. The method of claim 11, further comprising annealing the oxide layer to densify the oxide layer.

14. The method of claim 11, wherein the oxide layer comprises one or more of silicon oxide (SiO₂), silicon oxycarbonitride (SiOCN), silicon oxycarbide (SiOC), or silicon oxynitride (SiON).

15. The method of claim 11, wherein the silicon oxide (SiOx) layer comprises a silicon rich silicon oxide (SiOₓ) liner layer where x is in a range of from 1 to less than 2.

16. The method of claim 12, wherein the nitride layer comprises silicon nitride (SiₓN_{y}) or silicon carbonitride (SiCN).

17. The method of claim 12, wherein the nitride layer has a thickness in a range of from 1 nm to 25 nm.

18. The method of claim 12, wherein the process cycle forms an oxygen/nitrogen gradient where a concentration of nitrogen (N) is lowest at an interface with each of the plurality of first layers and highest in a middle of each of the plurality of lateral openings.

19. The method of claim 12, wherein the third sub-cycle comprises a rapid plasma oxidation (RPO) process.

20. A processing tool for forming a semiconductor device, the processing tool comprising:
a central transfer station having a plurality of processing chambers disposed around the central transfer station;
a robot within the central transfer station configured to move a substrate between the plurality of processing chambers;
a first processing chamber connected to the central transfer station, the first processing chamber configured to perform an atomic layer deposition process to deposit one or more of a nitride layer or an oxide layer on each of a plurality of first layers including a channel and a replacement gate material;
a second processing chamber within the processing tool accessible to the robot, the second processing chamber comprising one or more of a rapid plasma oxidation (RPO) chamber, a thermal oxidation chamber, or a rapid thermal annealing chamber configured to oxidize the nitride layer to form an oxide layer;
a third processing chamber connected to the central transfer station, the third processing chamber comprising a thermal annealing chamber configured to densify the oxide layer; and
a controller connected to the central transfer station, the robot, the first processing chamber, the rapid plasma oxidation (RPO) chamber, the thermal oxidation chamber, or the rapid thermal annealing chamber, the controller having configurations comprising a first configuration to move a substrate on the robot between the plurality of processing chambers; a second configuration to perform the atomic layer deposition of the nitride layer; a third configuration to perform the oxidation in the second processing chamber; and a fourth configuration to perform the densification of the oxide layer in the third processing chamber.
